(19) United States
(12) Patent Application Publication
(10) Pub. No.: US 2009/0098721 A1
(43) Pub. Date: Apr. 16, 2009

(54) METHOD OF FABRICATING A FLASH MEMORY

(76) Inventors: Michael-Y Liu, Chiayi City (TW); Hui-Hung Kuo, Kaohsiung County (TW); Hui-Min Hsu, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/873,400

(22) Filed: Oct. 16, 2007

(51) Int. Cl. H01L 21/3205

(52) U.S. Cl. 438/593; 257/E21.294

(57) ABSTRACT

A method of fabricating a flash memory includes providing a semiconductor substrate with STIs and an active area between two adjacent STIs along a first direction; successively forming a floating-gate insulating layer, a conductive layer, a dielectric layer, a control gate, and a cap layer on the semiconductor substrate; forming spacers on the sidewalls of the cap layer and the control gate; removing the dielectric layer, the conductive layer, and the floating-gate insulating layer not covered by the spacers and the cap layer; performing a selective epitaxial growth process to form an epitaxial layer on the exposed semiconductor substrate in the active area; and forming a source in the epitaxial layer and the semiconductor substrate in the active area.

### BACKGROUND OF THE INVENTION

1. Field of the Invention

The invention relates to a fabrication method of a flash memory, and more particularly, to a fabrication method by employing a selective epitaxial growth (SEG) process of a flash memory to improve the performance thereof.

2. Description of the Prior Art

Nonvolatile memories have the advantages of maintaining stored data while the power supply is interrupted, thus have been widely applied to information products. According to the bit numbers stored by a single memory cell, nonvolatile memories are divided into single-bit storage nonvolatile memories and dual-bit storage nonvolatile memories, wherein the former contains nitride read-only-memory (NROM), metal-oxide-nitride-oxide-silicon (MONOS) memories, and silicon-oxide-nitride-oxide-silicon (SONOS) memories, and the latter contains split-gate SONOS memories and split-gate MONOS memories. Comparing to the traditional single-bit storage nonvolatile memories, each memory cell of the split-gate SONOS memories or the split-gate MONOS memories provides two bits of storage, so that the split-gate SONOS or MONOS memories are capable of storing more data and have gradually become more and more popular in the nonvolatile memory device market.

The conventional fabrication method of a split-gate flash memory includes forming shallow trench isolations (STIs) on the surface of a semiconductor substrate, successively forming an oxide layer and a first polysilicon layer for serving as an floating gate on the semiconductor substrate, removing a portion of the first polysilicon layer, successively forming a first dielectric layer, a second polysilicon layer as a control gate, and a cap layer on the semiconductor substrate, and performing an etching process to remove portions of the cap layer and the second polysilicon layer for defining a control gate. Then, spacers are formed on two sides of the cap layer and the control gate, and the spacers and the cap layer are taken as a mask for performing an etching process to remove portions of the first dielectric layer, the first polysilicon layer, and the oxide layer to form at least a stacked structure. Thereafter, a second dielectric layer is formed on the outside of the stacked structure, and an erase gate and word lines are sequentially formed to complete the fabrication of the main elements of the split-gate nonvolatile flash memory.

However, since a portion of the first polysilicon layer is removed before the stacked structure is formed, there are only the oxide layer and the first dielectric layer, without the first polysilicon layer, remaining on a certain part of the semiconductor substrate. Accordingly, when the etching process is performed for removing a portion of the first polysilicon layer by taking the cap layer and spacers as a mask, the surface of such part of the semiconductor substrate is also removed, accompanied with pluralities of active area (AA) trenches formed in the common source region. Therefore, the following formed second dielectric layer and erase gate will be formed in the AA trenches, easily causing point discharge effect in the AA trenches when the flash memory is under operation, which brings the failure of programming or defects of the flash memory. As a result, the split-gate flash memories fabricated according to the prior art usually have disadvantages of less stability and short lifetime.

### SUMMARY OF THE INVENTION

It is a primary objective of the claimed invention to provided a fabrication method of a flash memory to solve the above-mentioned problems of defects and short lifetime of the flash memory resulting from the AA trenches formed during the etching process.

According to the claimed invention, a method of fabricating a flash memory is provided. First, a semiconductor substrate with a plurality of shallow trench isolations (STIs) is provided, an active area is defined between adjacent STIs along a first direction. Then, a floating-gate insulating layer, a first conductive layer, a dielectric layer, a control gate, and a cap layer are successively formed on the semiconductor substrate, and spacers are formed on two sides of the cap layer and the control gate. An etching process is performed to remove portions of the dielectric layer, the first conductive layer, and floating-gate insulating layer not covered by the spacers and the cap layer so as to form a stacked structure next to the active area. Then, an SEG process is performed to form an epitaxial layer on the exposed semiconductor substrate in the active area. Finally, a source is formed in the epitaxial layer and the semiconductor substrate in the active area.

It is an advantage of the claimed invention that an epitaxial layer is formed on the surface of the semiconductor substrate to planarize the surface of the semiconductor substrate before forming the source, such that the following-formed elements, such as the erase gate or the erase-gate insulating layer, can be fabricated above the surface of the semiconductor substrate. As a result, the problems such as point discharge effect in the prior art caused by forming elements in a recess or trench of the substrate can be effectively solved, which may improve the performance of the memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-15 are schematic diagrams of the method of fabricating a flash memory according to the present invention.

### DETAILED DESCRIPTION

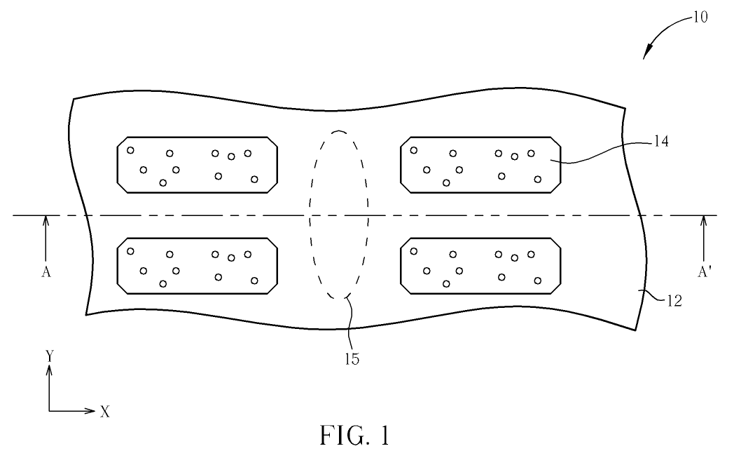

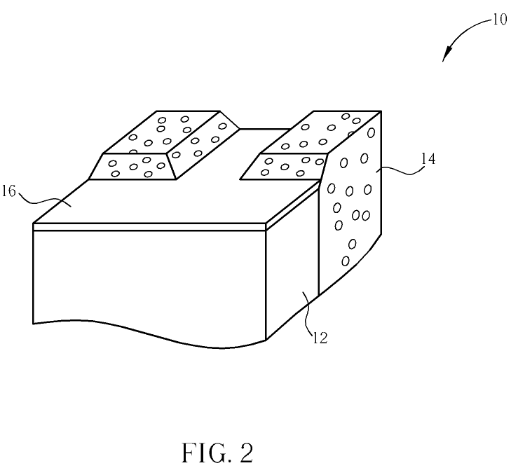

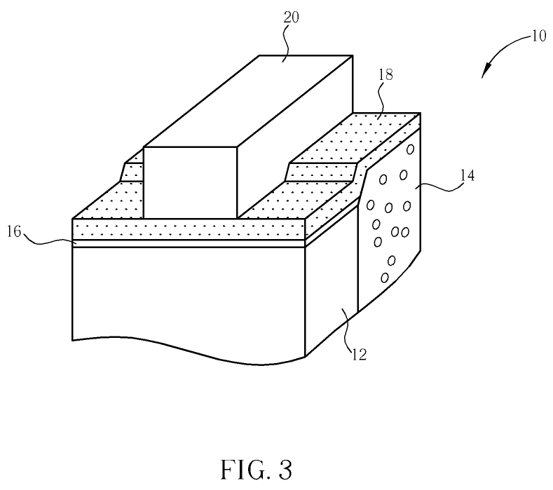

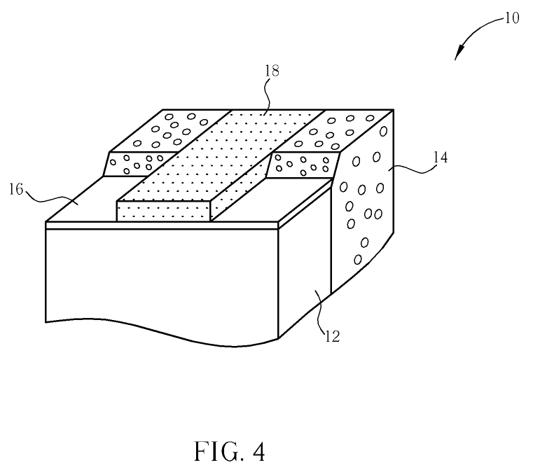

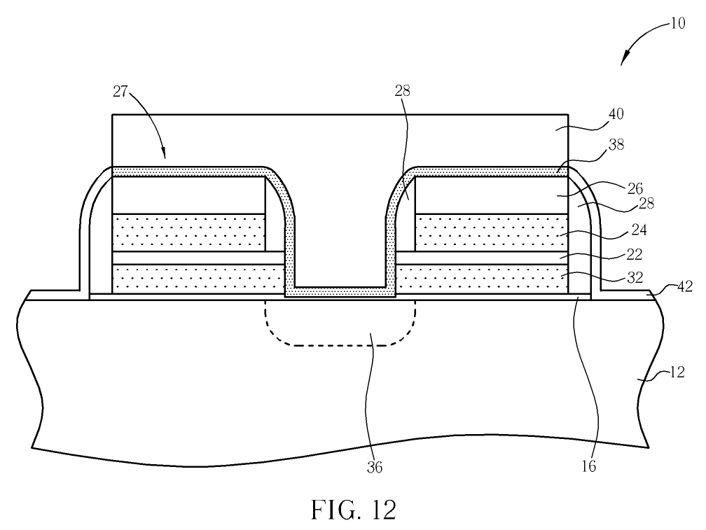

FIGS. 1-15 are schematic diagrams of a preferable embodiment of the method of fabricating a split-gate flash memory according to the present invention, while FIG. 1 is a top-view diagram; FIGS. 2-11 and FIG. 14 are three-dimensional (3D) diagrams of the sectional view along the Y-direction in FIG. 1; and FIGS. 12, 13 and 15 are sectional views along the X-direction in FIG. 1. As shown in FIG. 1, when fabricating the present invention split-gate flash memory 10, a semiconductor substrate 12 is provided at first, wherein the semiconductor substrate 12 comprises a plurality of STIs 14 thereon. The semiconductor substrate 12 may be a silicon substrate, a P-type substrate, or an N-type substrate. The portion positioned between adjacent STIs 14 along the Y-direction, for example the portion marked by the dotted line, is defined as an active area 15 of the split-gate flash memory 10. Referring to FIG. 2, a dry oxidation process is performed to form an oxide layer on the surface of the portions of the semiconductor substrate 12 without the STIs 14, which serves as the floating-gate insulating layer 16. Then, with reference to FIG. 3, a first conductive layer 18 is deposited on the semiconductor substrate 12, and the first conductive layer 18 preferably comprises polysilicon materials. A first photolithography-etching-process (PEP) is executed by forming a patterned photoresist layer 20 on the first conductive layer 18 and removing the first conductive layer 18 on the STIs 14 along the X-direction through an etching process, meanwhile the patterned photoresist layer 20 is taken as an etching mask to define a floating gate pattern. As shown in FIG. 4, during the first PEP, the patterned photoresist layer 20 is taken as an etching mask to perform the etching process to the first conductive layer 18 for removing a portion of the first conductive layer 18 not covered by the patterned photoresist layer 20 and for exposing the STIs 14.

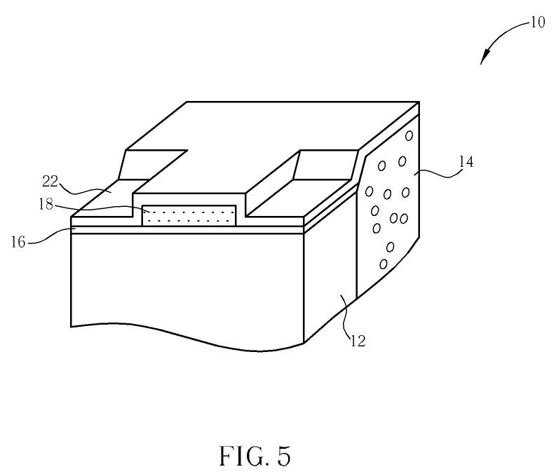

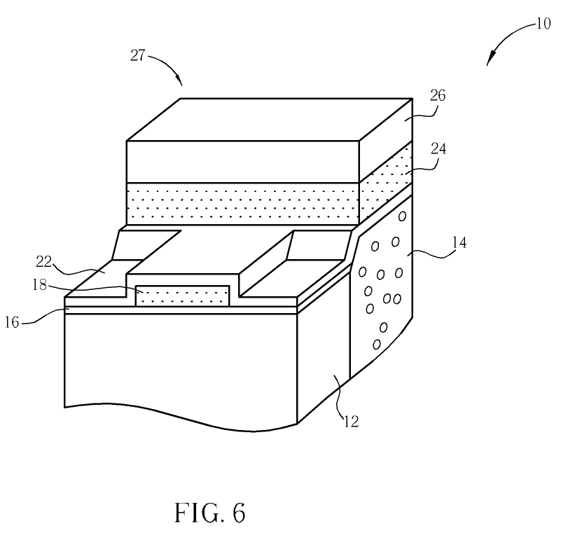

Thereafter, referring to FIG. 5, a dielectric layer 22 is formed on the semiconductor substrate 12, which preferably comprises oxide-nitride-oxide (ONO) dielectric materials. Then, as shown in FIG. 6, a patterned control gate 24 and a cap layer 26 are successively formed on the semiconductor substrate 12 to cover portions of the dielectric layer 22, the first conductive layer 18, and the STIs 14. The control gate 24 may comprise polysilicon and tungsten silicide (WSi) materials, while the cap layer 26 may comprise tetraethylorthosilicate (TEOS) silicon nitride materials with a precursor of TEOS during its formation. The formation of the patterned control gate 24 and the cap layer 26 comprises successively depositing a second conductive layer and a material layer of the cap layer on the semiconductor substrate 12, performing a second PEP to remove portions of the second conductive layer and the material layer of the cap layer to form second conductive layer into the control gate 24 and the patterned cap layer 26 respectively.

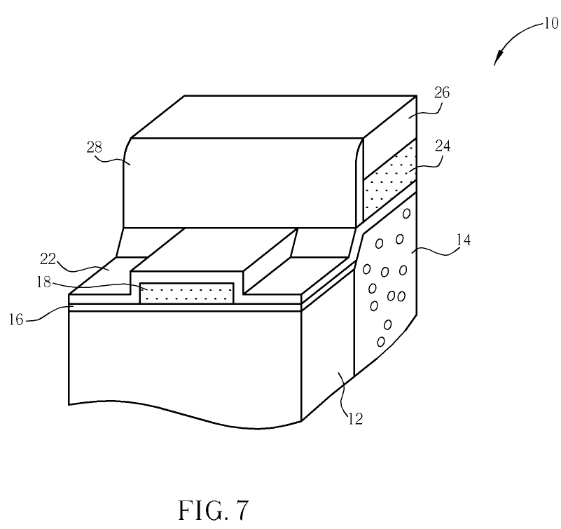

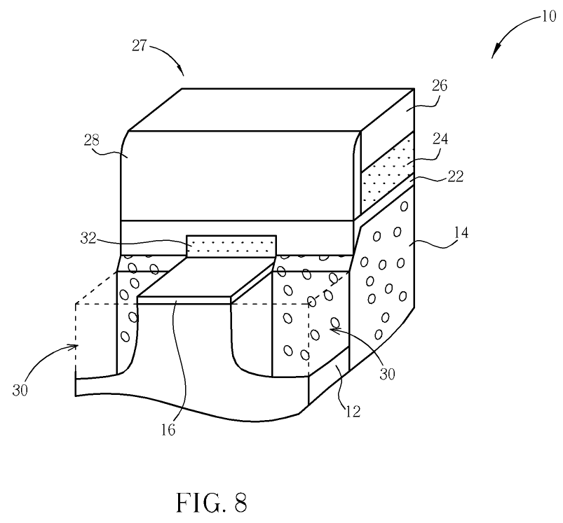

Please refer to FIG. 7. A silicon nitride layer is formed on the semiconductor substrate 12, and an anisotropic etching process is carried out to form spacers 28 on two sides of the control gate 24 and the cap layer 26. Then, as shown FIG. 8, the cap layer 26 and the spacers 28 are taken as an etching mask to perform an etching process, while etching gas for oxide and polysilicon materials are employed as the etchant sequentially. During this etching process, portions of the dielectric layer 22 and the first conductive layer 18 not covered by the cap layer 26 and the spacers 28 are removed. Noted that below a certain portion of the dielectric layer 22, there is no first conductive layer 18 existing, and therefore the underneath floating-gate insulating layer 16 and semiconductor substrate 12 are also removed during the etching process, which forms several AA trenches 30 in the common source region. With respect to FIG. 1, the AA trenches 30 are formed in the active area 15 of the split-gate flash memory 10, positioned between two adjacent STIs 14. After the above-mentioned etching process, a stacked structure 27 is formed, which comprises the cap layer 26, the control gate 24, the dielectric layer 22, a floating gat 32 formed with the remaining first conductive layer 18, and the floating-gate insulating layer 16 form top to bottom. In addition, a side of the stacked structure 27 is positioned next to the active area 15.

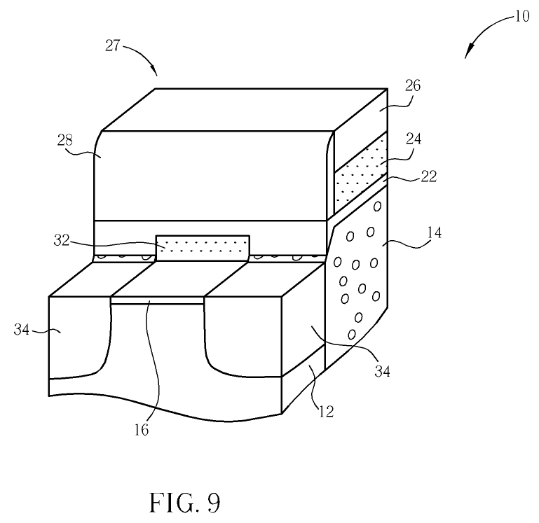

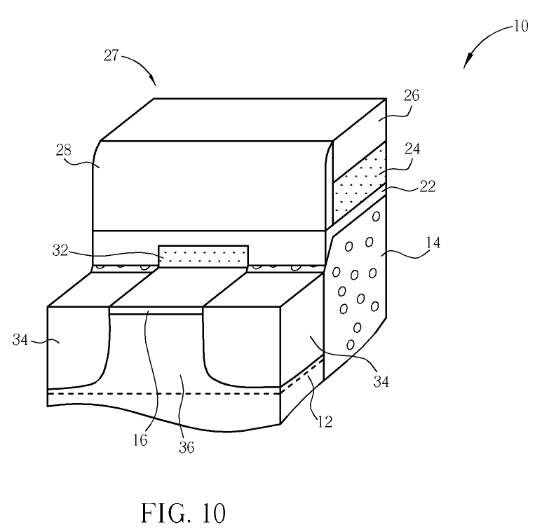

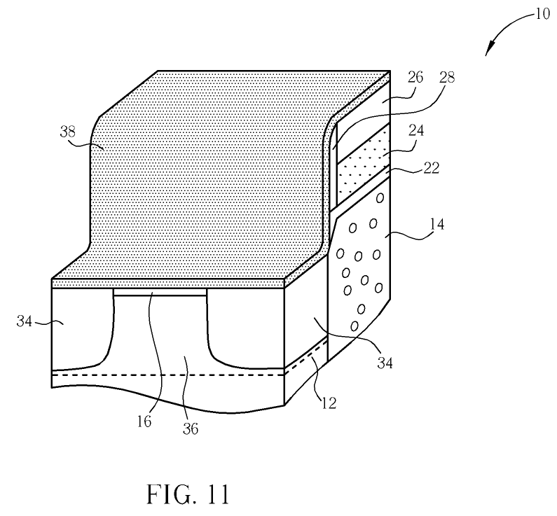

Thereafter, as shown in FIG. 9, a SEG process is performed to form an epitaxial layer 34 inside each AA trench 30. Preferably, the top surface of the epitaxial layers 34 is approximately as high as or higher than the surface of the semiconductor substrate 12 in the active area 15 without the epitaxial layer 34 thereon. Referring to FIG. 10, an ion implantation process is performed to form a common source 36 in the epitaxial layer 34 and the surface of the semiconductor substrate 12 below the floating-gate insulating layer 16. As shown in FIG. 11, a high temperature oxidation (HTO) process is carried out to form an HTO layer 38 on the semiconductor substrate 12, serving as an erase-gate insulating layer and covering the surfaces of the common source 36, spacers 28, and cap layer 26.

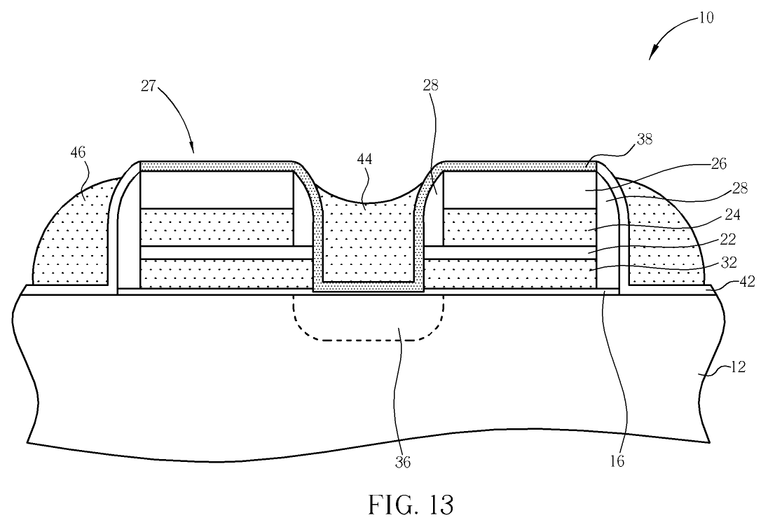

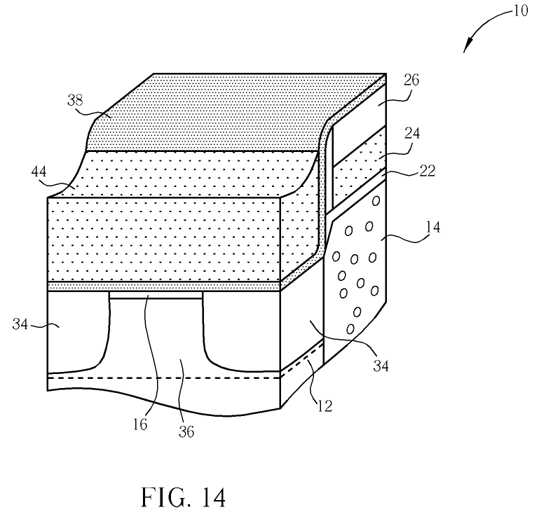

Referring to FIG. 12, FIG. 12 shows the following formed structure of the split-gate flash memory 10 of FIG. 11, while FIG. 12 illustrates a section view of the split-gate flash memory 10 along the X-direction (such as along line A-A′) in FIG. 1 and therefore two stacked structures 27 are shown in FIG. 12. After the HTO layer 38 is formed, a patterned photoresist layer 40 is formed on the semiconductor substrate 12 to cover the active area 15 of the split-gate flash memory 10 and the HTO layer 38 above the cap layer 26 and the common source 36. Then, the HTO layer 38 not covered by the patterned photoresist layer 40 is removed, and an oxide layer 42 is formed on the exposed semiconductor substrate 12 and spacers 28 for serving as a word-line insulating layer that is positioned at a side of each stacked structure 27 opposite to the common source 36. As shown FIG. 13, after removing the patterned photoresist layer 40, a deposition process is carried out to blankly form a third conductive layer, such as a polysilicon layer, on the semiconductor substrate 12. Then, an etching back process is performed to remove portions of the third conductive layer such that the height of the remaining third conductive layer is less than that of the stacked structures 27. As a result, the remaining third conductive layer becomes an erase gate 44 and a word line 46 on the common source 36 and at a side of each stacked structure 27 respectively. Under this situation, a 3D diagram of a section view of the split-gate flash memory 10 along the Y-direction in FIG. 1 is illustrated in FIG. 14.

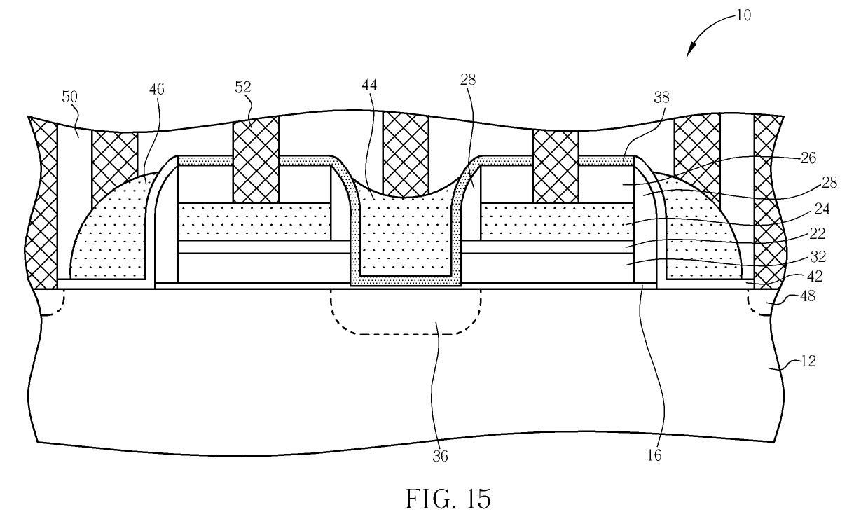

Finally, as shown in FIG. 15, an ion implantation process is executed to form a drain 48 at a side of each word line 46 on the surface of the semiconductor substrate 12. Then, an interlayer dielectric layer 50 is formed, and contact plugs 52 of the word lines 46, drains 48, control gates 24, and erase gate 44 are formed in the interlayer dielectric layer 50 so as to accomplish the fabrication of the main elements of the split-gate flash memory 10.

In contrast to the prior art, the fabrication method of a flash memory according to the present invention comprises forming an epitaxial layer in the AA trenches before fabricating the HTO layer and erase gate above the epitaxial layer or AA trenches. Therefore, the sharp profiles of the common source and the HTO layer resulting from the AA trenches in the prior art, causing point discharge effect and memory defects, are avoided. As a result, according to the present invention method, a flash memory with a long lifetime and high stability can be fabricated through simple processes, and the fabricated flash memory having a structure similar to the flash memories in current use has a wide application field.

Those skilled in the art will readily observe that numerous modifications and alterations of the device and method may be made while retaining the teachings of the invention.

What is claimed is:

1. A method of fabricating a flash memory, comprising:
providing a semiconductor substrate with a plurality of shallow trench isolations (STIs) thereon, an area between two adjacent STIs along a first direction being defined as an active area;
successively forming a floating-gate insulating layer, a first conductive layer, a dielectric layer, a control gate, and a cap layer on the semiconductor substrate;
forming spacers on two sides of the cap layer and the control gate respectively;
performing an etching process to remove portions of the dielectric layer, the first conductive layer, and the floating-gate insulating layer not covered by the spacers and the cap layer so as to form a stacked structure next to the active area;
performing a selective epitaxial growth (SEG) process to from an epitaxial layer on the exposed semiconductor substrate in the active area; and
performing an ion implantation process to form a source in the epitaxial layer and the semiconductor substrate in the active area.

2. The method of claim 1, wherein a top surface of the epitaxial layer is approximately as high as or higher than a top surface of the semiconductor substrate in the active area without the epitaxial layer thereon.

3. The method of claim 1, wherein the first conductive layer comprises polysilicon materials.

4. The method of claim 1, wherein the step of successively forming the floating-gate insulating layer, the first conductive layer, the dielectric layer, the control gate, and the cap layer on the semiconductor substrate comprises:
forming the floating-gate insulating layer on the semiconductor substrate;
forming the first conductive layer on the floating-gate insulating layer;
performing a first photolithography-etching-process (PEP) to remove a portion of the first conductive layer;
forming the dielectric layer on the semiconductor substrate to cover the first conductive layer;
successively forming a second conductive layer and the cap layer on the semiconductor substrate; and
performing a second PEP to remove portions of the second conductive layer and the cap layer for forming the second conductive layer into the control gate.

5. The method of claim 4, wherein the step of removing a portion of the first conductive layer comprises removing the first conductive layer above the STIs along a second direction.

6. The method of claim 1, further comprising:
forming an erase-gate insulating layer on the source;
forming a word-line insulating layer on the semiconductor substrate at a side of the stacked structure opposite to the source;
forming a third conductive layer on the semiconductor substrate; and
performing an etching back process to remove a portion of the third conductive layer so that a height of the third conductive layer is less than a height of the stacked structure and an erase gate and at least a word line are formed on the source and the word-line insulating layer respectively.

7. The method of claim 1, wherein the dielectric layer comprises oxide-nitride-oxide (ONO) materials.

8. The method of claim 1, wherein the flash memory is a split-gate memory.
